(19) United States
(12) Patent Application Publication
(10) Pub. No.: US 2013/0043517 A1
(43) Pub. Date: Feb. 21, 2013

(54) Semiconductor Structure And Method For Manufacturing The Same

(71) Applicants: Haizhou Yin, Poughkeepsie, NY (US); Zhijiong Luo, Poughkeepsie, NY (US); Huilong Zhu, Poughkeepsie, NY (US)

(72) Inventors: Haizhou Yin, Poughkeepsie, NY (US); Zhijiong Luo, Poughkeepsie, NY (US); Huilong Zhu, Poughkeepsie, NY (US)

(21) Appl. No.: 13/505,731

(22) PCT Filed: Dec. 1, 2011
(86) PCT No.: PCT/CN2011/083325

§ 371 Date: May 2, 2012

(30) Foreign Application Priority Data
Aug. 19, 2011 (CN) 201110238839.5
Dec. 1, 2011 (CN) PCT/CN2011/083325

(51) Int. Cl. H01L 29/78; H01L 21/336

(52) U.S. Cl. 257/288; 438/299; 257/E21.409; 257/E29.255

(57) ABSTRACT

The present invention provides a method for manufacturing a semiconductor structure, which comprises: providing a substrate, and forming a dielectric layer and a dummy gate layer on the substrate; performing doping and annealing to the dummy gate layer; patterning the dummy gate layer to form a dummy gate, wherein the top cross section of the dummy gate is larger than the bottom cross section of the dummy gate; forming sidewall spacers and source/drain regions; depositing an interlayer dielectric layer and planarizing the same; removing the dummy gate to form an opening within the sidewall spacers; and forming a gate in the opening. Accordingly, the present invention further provides a semiconductor structure. The present invention proposes to form a dummy gate in the shape of a reverse taper, which is capable of alleviating processing difficulty of removing the dummy gate and filling gate material at subsequent steps, and thereby favorably avoiding occurrence of voids or the like and enhancing reliability of devices.

The present application claims priority benefit of Chinese patent application No. 201110238839.5, filed on 19 Aug. 2011, entitled “SEMICONDUCTOR STRUCTURE AND METHOD FOR MANUFACTURING THE SAME”, which is herein incorporated by reference in its entirety.

### FIELD OF THE INVENTION

The present invention relates to the field of semiconductor manufacturing, particularly, to a semiconductor structure and a method for manufacturing the same.

### BACKGROUND OF THE INVENTION

In order to improve the performance and integration level of integrated circuit chips, feature sizes of devices have been continuously scaled down according to Moore's law and now have already come into the age of nanometer. Along with downscaling of device sizes, the thickness of gate dielectric layer is also reduced continuously. However, ultra-thin gate dielectrics cause very severe gate tunneling currents, and poly-Si gate depletion effect also brings about serious challenge to performances and reliability of semiconductor devices. It has almost become an indispensable manufacturing technology for 45 nm and below to replace traditional SiON gate dielectrics/poly-Si gates with high-k gate dielectrics/metal gates. Specifically, the manufacturing of a high-k dielectric/metal gate may be categorized into gate-first processes and gate-last processes. In the gate-last processes, gates are manufactured after formation of source/drain regions, so as to avoid an annealing process performed under high temperature for source/drain regions, namely, to avoid problems like interface reactions, change of metal gate work function, increase in PMOS threshold voltages arising from the high temperature processes.

In the gate-last processes, dummy gates have to be formed first, then ion implantation and annealing are performed for source/drain regions; finally, dummy gates are removed, and metal is filled to form metal gates. However, along with ongoing downscaling in feature sizes of devices, the gate length of semiconductor devices is reduced to no greater than 20 nm. Thus, filling metal to form a gate in such a limited dimension would cause occurrence of voids, gaps, or the like, thereby bringing about adverse impacts on performances and reliability of semiconductor devices.

### SUMMARY OF THE INVENTION

It is an object of the present invention to at least overcome the abovementioned technical defects and to provide a method for manufacturing a semiconductor device and a structure of the semiconductor device. The method is capable of alleviating process difficulty during filling gate material, so as to avoid occurrence of voids and to improve reliability of devices. In order to achieve aforesaid object, the present invention provides a method for manufacturing a semiconductor structure, comprising:

(a) providing a substrate, and forming a dielectric layer and a dummy gate layer on the substrate;
(b) performing doping and annealing to the dummy gate layer;
(c) patterning the dummy gate layer to form a dummy gate, wherein the top cross section of the dummy gate is larger than the bottom cross section of the dummy gate;
(d) forming sidewall spacers and source/drain regions;
(e) depositing an interlayer dielectric layer and planarizing the interlayer dielectric layer;
(f) removing the dummy gate to form an opening within the sidewall spacers; and
(g) forming a gate in the opening.

At the step (b), such a concentration of dopant ion that is gradually lower inwards from the surface is formed within the dummy gate layer. In the subsequent patterning step, an appropriate etching method is selected, thus the dummy gate layer may be etched gradually faster inwards from its surface, so as to form a gate structure in the shape of a reverse taper with a large top surface but a small bottom.

In another aspect, the present invention further provides a semiconductor structure, which comprises a substrate, a gate stack, sidewall spacers and source/drain regions, wherein:

The gate stack is located on the substrate and comprise a gate dielectric layer and a gate, and the top cross section of the gate is larger than the bottom cross section of the gate, the gate dielectric layer being sandwiched between the gate and the substrate, or alternatively, the gate dielectric layer being covering the sidewalls and the bottom of the gate;

the sidewall spacers are located on both sides of the gate stack;

the source/drain regions are formed in the substrate and located on opposite sides of the gate stack.

According to the semiconductor structure and the method for manufacturing the same as provided by the present invention, a gate structure in the shape of a reverse taper is formed. Thus, the gate filling can be performed optimally after the removal of the dummy gate, so as to avoid voids, gaps, or the like. Accordingly, the processing difficulty is greatly alleviated and reliability of devices is enhanced as well.

### BRIEF DESCRIPTION OF THE DRAWINGS

Aforesaid and/or additional characteristics and advantages of the present invention are made more evident and easily understood according to perusal of the following detailed description of exemplary embodiment(s) in conjunction with accompanying drawings, wherein:

FIG. 1 illustrates a flowchart of a method for manufacturing a semiconductor structure according to an embodiment of the present invention;

FIGS. 2 to 16 illustrate cross-sectional structural diagrams of a semiconductor structure at respective stages of the method for manufacturing a semiconductor structure according to the flowchart of the embodiment of the present invention as shown in FIG. 1;

FIG. 17 illustrates relationship data chart of etching speed of <100> Si with KOH etching solution against doping concentration of boron.

### DETAILED DESCRIPTION OF THE INVENTION

Embodiments of the present invention are described in detail here below, wherein examples of the embodiments are illustrated in the drawings, in which same or similar reference signs throughout denote same or similar elements or elements have same or similar functions. It should be appreciated that the embodiments described below in conjunction with the drawings are illustrative and are provided for explaining the prevent invention only, thus shall not be interpreted as limitations to the present invention. Various embodiments or examples are provided here below to implement different structures of the present invention. To simplify the disclosure of the present invention, description of components and arrangements of specific examples is given below. Of course, they are illustrative only and not limiting the present invention. Moreover, in the present invention, reference numbers and/or letters may be repeated in different embodiments. Such repetition is for purposes of simplification and clarity, yet does not denote any relationship between respective embodiments and/or arrangements being discussed. Furthermore, the present invention provides various examples for various process and materials. However, it is obvious for a person of ordinary skill in the art that other processes and/or materials may be utilized alternatively. In addition, the following structure in which a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. It should be noted that the component(s) illustrated in the drawings might not be drawn to scale. Description of conventional components, processing technology and crafts are omitted herein in order not to limit the present invention unnecessarily.

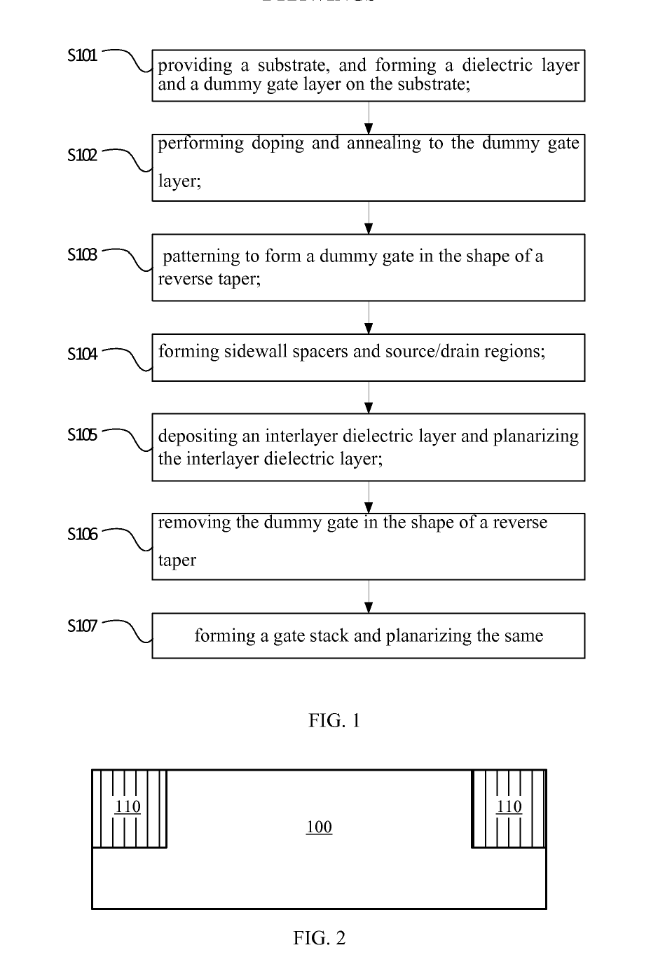

FIG. 1 illustrates a flowchart of a method for manufacturing a semiconductor structure according to an embodiment of the present invention, and FIGS. 2 to 16 illustrate cross-sectional structural diagrams of the semiconductor structure at respective stages of the method for manufacturing the semiconductor structure according to the flowchart of the embodiment of the present invention as shown in FIG. 1. Here below, the method for manufacturing a semiconductor structure illustrated in FIG. 1 will be described in detail in conjunction to FIGS. 2 to 16. However, it should be noted that the accompanying drawings of the embodiments of the present invention might not be necessarily drawn to scale but are provided for purpose of illustration only.

With reference to FIGS. 2 to 4, at step S101, a substrate 100 is provided, and a dielectric layer 200 and a dummy gate layer 210 are formed on the substrate 100.

In the present embodiment, the substrate 100 comprises a Si substrate (e.g. Si wafer). According to known design requirements (e.g. those for a P-type substrate or an N-type substrate), the substrate 100 may be of various doping configurations. The substrate 100 in other embodiments may comprise other semiconductors, for example, germanium, or a compound semiconductor (e.g. materials of III-V families) like SiC, GaAs, and InAs. Typically, the substrate 100 may have, but is not limited to, a thickness of around several hundred micrometers, which, for example, may be in the range of 200 μm-800 μm.

Specifically, isolation regions may be formed in the substrate 100, for example, shallow trench isolation (STI) structures 110 as shown in FIG. 2, so as to electrically isolate consecutive Field-Effect transistor devices. Field implantation also may be performed on the surface of the substrate 100.

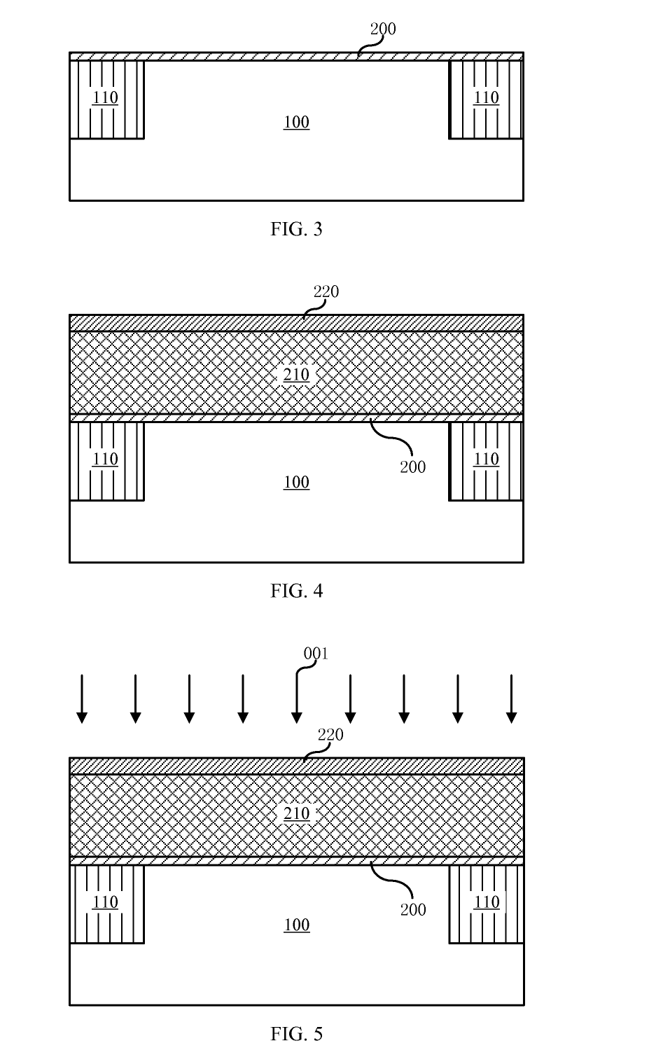

As shown in FIG. 3, a dielectric layer 200 is formed on the substrate 100 and may comprise SiO₂, Si₃N₄, or at least one high-k material selected from a group consisting of HfO₂, HfSiO, HfSiON, HfTaO, HfTiO, HfZrO, Al₂O₃, La₂O₃, ZrO₂, and LaAlO. Typically, the thickness of the dielectric layer 200 is in the range of 2 nm to 10 nm.

Next, as shown in FIG. 4, poly-Si is deposited on the dielectric layer 200 to form a dummy gate layer 210 with a thickness of about 10 nm to 200 nm. The poly-Si dummy gate layer 210 may be formed by means of sputtering, chemical vapor deposition, or any appropriate method. Preferably, a hard mask layer 220 may further be formed on the dummy gate layer 210, for example, by means of depositing at least one material selected from Si₃N₄, SiO₂, SiO₂N₂, and SiC, so as to provide protection to the top of the dummy gate layer 210, as shown in FIG. 4.

With reference to FIGS. 1 and 5, step S102 is performed to perform doping and annealing on the dummy gate layer 210. In the present embodiment, a first ion implantation 001 is performed to dope the dummy gate layer 210 so as to form a doping profile. Alternatively, the doping may be performed through diffusion in other embodiments of the present invention. The dopant is B, P, or As. The implanted ions are kept to reach a maximum concentration on the upper surface of the dummy gate layer 210 by adjusting parameters, such as ion particle energy, ion implantation voltage, implantation dose, in conjunction with the blocking effect from the hard mask layer 220. Then, the annealing is performed such that the distribution of doping concentration within the dummy gate layer 210 is gradually lower inwards from the surface of the dummy gate layer 210. The doping concentration at the surface of the dummy gate layer 210 is in the range of 1×10¹⁹ cm⁻³ to 1×10²¹ cm⁻³.

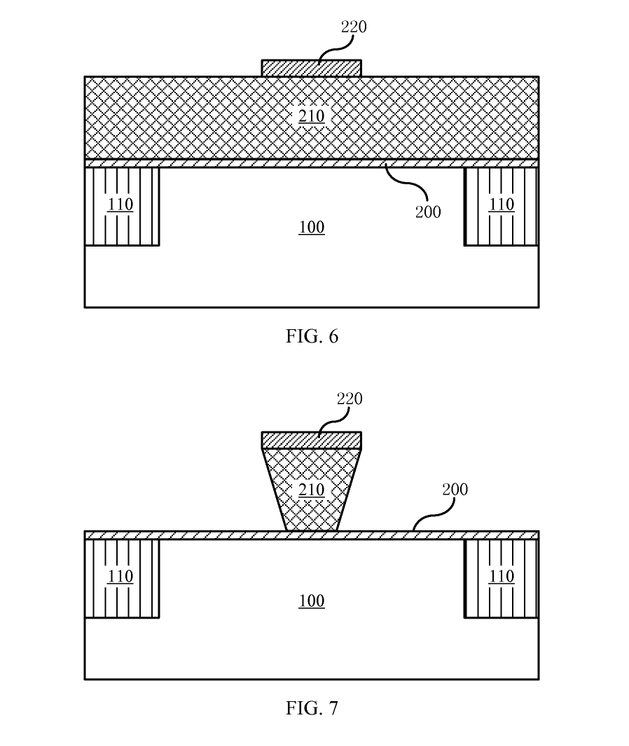

With reference to FIGS. 1, 6 and 7, step S103 is performed to pattern the dummy gate layer to form a dummy gate 210, wherein the dummy gate is in the shape of a reverse taper with a larger top surface and a smaller bottom, and the cross section of the dummy gate is a reverse trapezoid. FIG. 6 illustrates the cross-sectional view of the patterned hard mask layer 220. FIG. 7 illustrates a cross-sectional view of patterned dummy gate layer. The dummy gate layer may be etched through a wet etching method using an etching solution, such as Potassium hydroxide (KOH), Tetramethylammonium hydroxide (TMAH), and Ethylenedamine pyrocatochol (EDP). FIG. 17 illustrates a relationship data chart of the etching speed of <100> Si with KOH etching solution against the doping concentration of B. It is shown that when the doping concentration is less than the threshold concentration of 1×10¹⁹ cm⁻³, the etching speed is substantially a constant. However, when it exceeds the threshold concentration, the etching speed is in reverse proportion to 4 square times of the doping concentration, and the etching speed becomes so small that the etching may be regarded as stopped at a certain concentration. In respect to dopants like P and As, they also have similar trends where the etching speed changes proportionally to the doping concentration. Preferably, in the present embodiment, the dummy gate layer is patterned using RIE dry etching combined with wet etching. Firstly, the dummy gate layer is etched through RIE dry etching with the hard mask layer 220 as a mask, such that the obtained dummy gate has sidewalls that are approximately upright. Then, wet etching is performed with an appropriate etching solution, such as KOH, TMAH, and EDP, and the dummy gate 210 in the shape of a reverse taper is obtained by controlling concentration of etching solution, temperature, etching period, etc.

With reference to FIGS. 1 and 8-10, step S104 is performed to form sidewall spacers 400 and source/drain regions 310.

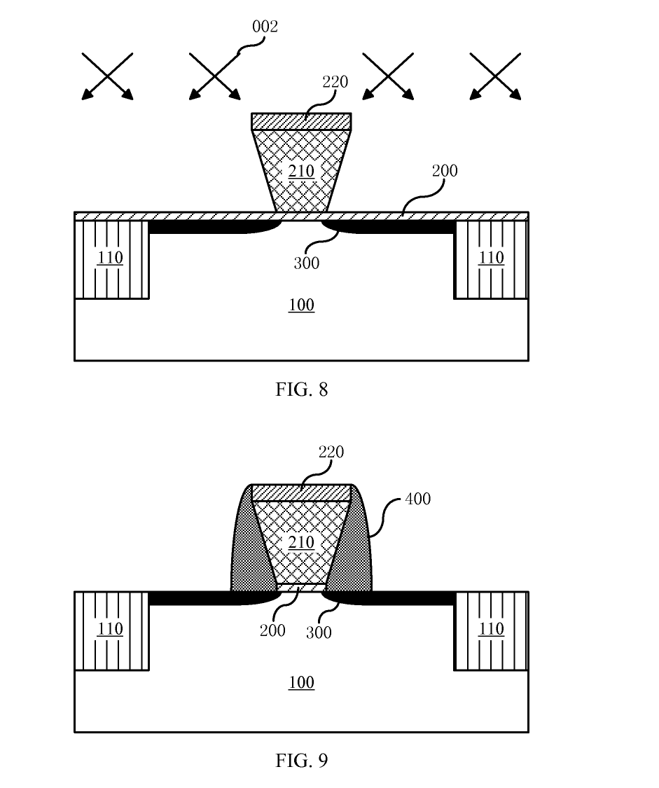

Optionally, step S104 may further comprise forming source/drain extension regions 300 firstly. Shallow source/drain extension regions 300 may be formed in the substrate 100 by means of low-energy and large-tilt-angle implantation (a second ion implantation 002), wherein P-type or N-type dopants may be implanted into the substrate 100. For example, the source/drain extension regions 300 may be P-type doped Si for PMOS, while the source/drain extension regions 300 may be N-type doped Si for NMOS. Optionally, annealing is performed on the semiconductor structure to activate the dopants in the source/drain extension regions 300. Annealing may be implemented by instant annealing, spike annealing, or other methods as appropriate. In other embodiments of the present invention, the annealing process may be performed after the formation of source/drain regions 310. Since the thickness of the source/drain extension regions 300 is small, short-channel effects can be suppressed effectively. FIG. 8 illustrates the cross-sectional view of the structure after the source/drain extension regions 300 have been formed. Optionally, it is also applicable to form a Halo implantation region by angled ion implantation.

As shown in FIG. 9, sidewall spacers 400 are formed after the formation of the source/drain extension regions. The sidewall spacers 400 are formed on sidewalls of the dummy gate 210 for isolating the gate. The sidewall spacers 400 may be formed with at least one material selected from a group consisting of Si₃N₄, SiO₂, SiO₂N₂, SiC, and/or other material as appropriate, by deposition-etching process. The sidewall spacers 400 may be in a multi-layer structure, whose thickness may be in a range of 10 nm to 100 nm, for example, 30 nm, 50 nm, or 80 nm.

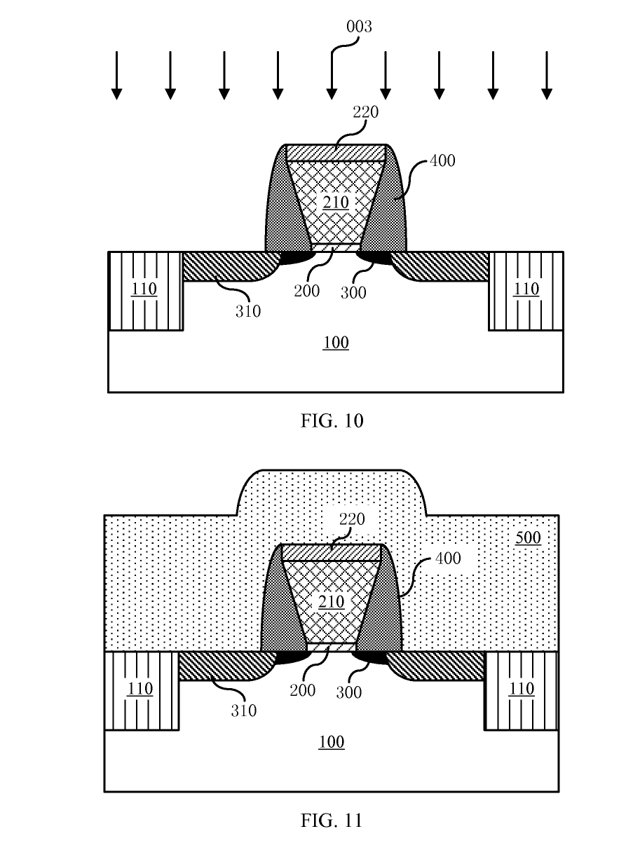

After formation of sidewall spacers, source/drain regions 310 are formed by heavily doping ion implantation. The source/drain regions 310 are located within the substrate and, as shown in FIG. 10, on opposite sides of the dummy gate 210, and may be formed by implanting P-type or N-type dopants into the substrate 100. For example, the source/drain region 310 may be P-type doped Si for PMOS, while the source/drain regions 310 may be N-type doped Si for NMOS. The source/drain regions 310 may be formed by lithography, ion implantation, diffusion, and/or other processes as appropriate. In the present embodiment, source/drain regions 310 are formed by a third ion implantation 003. Then, annealing is performed to the semiconductor structure to activate dopants in the source/drain regions 310, wherein annealing may be implemented by a process as appropriate including instant annealing, spike annealing or the like. In the present embodiment, the source/drain regions 310 are located in the substrate 100, while in other embodiments, source/drain regions 310 may be raised source/drain structures formed by selective epitaxial growth, wherein the top surfaces of the epitaxially grown portions of the raised source/drain are higher than the bottom of the dummy gate (herein, the bottom of the dummy gate indicates the interface between the dummy gate and the substrate 100).

Optionally, the exposed dielectric layer 200 may be removed through etching after the formation of the dummy gate 210; or alternatively, the exposed dielectric layer 200 may be removed through etching after the formation of source/drain regions.

Optionally, after the formation of the source/drain regions 310, a layer of metal like Ti, Pt, Co, Ni, and Cu may be deposited on the substrate, so as to form a silicide contact layer (not shown) on the source/drain regions 310 after annealing.

With reference to FIGS. 1, 11 and 12, step S105 is performed to deposit an interlayer dielectric layer 500, which then is planarized. As shown in FIG. 11, the interlayer dielectric layer 500 may be formed by chemical vapor deposition (CVD), high-density plasma CVD, spin coating, and/or other processes as appropriate. The material of the interlayer dielectric layer 500 may be at least one material selected from a group consisting of SiO₂, doped SiO₂ (e.g. FSG, BSG, PSG, BPSG), and a low-k dielectric material (e.g. black diamond, coral). The thickness of the interlayer dielectric layer 500 may be in a range of 40 nm-150 nm, for example, 80 nm, 100 nm, or 120 nm. The interlayer dielectric layer 500 may be in a multi-layer structure, namely, two neighboring layers may be made of different materials.

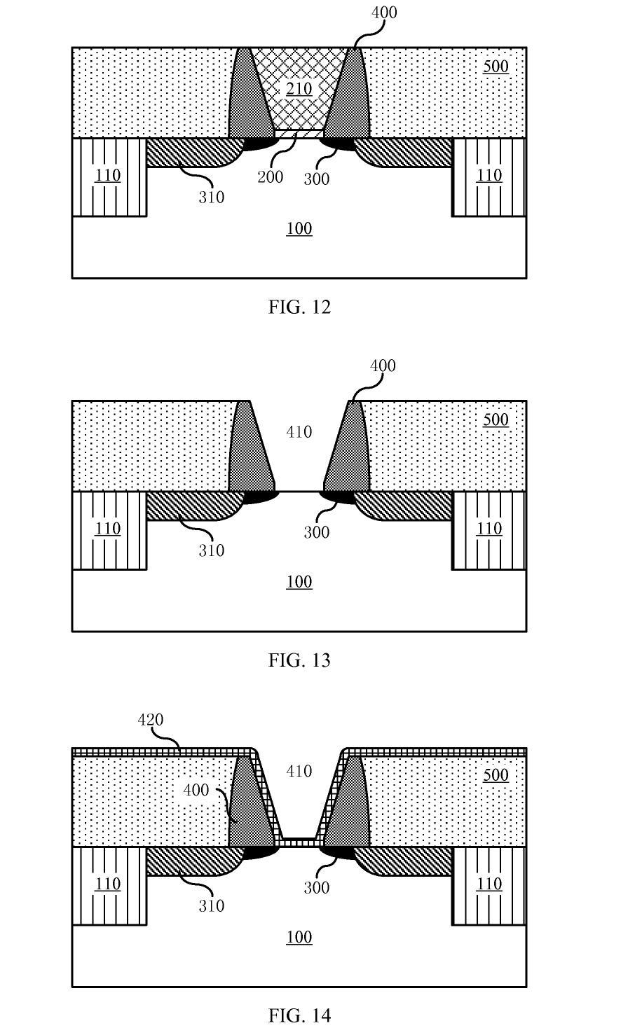

Next, the interlayer dielectric layer 500 is planarized to expose the upper surface of the dummy gate 210, as shown in FIG. 12. The interlayer dielectric layer 500 may be thinned by means of chemical mechanical polish (CMP). Meanwhile, the hard mask layer 220 on the dummy gate 210 is also processed by chemical mechanical polish (CMP), such that the upper surface of the dummy gate 210 is level with the upper surface of the interlayer dielectric layer 500 (herein, the term “level with” means that the difference between the heights of two objects is in the range permitted by process tolerance).

With reference to FIGS. 1 and 3, step S106 is performed to remove the dummy gate 210 so as to form an opening 410. Specifically, the dummy gate 210 may be removed by dry RIE etching, or by wet etching with hot phosphoric acid, HF—HNO₃—CH₃COOH(HNA), KOH, TMAH, or EDP. The dielectric layer 200 located below the dummy gate 210 may be kept as a gate dielectric layer of the semiconductor device. In the present embodiment, the dielectric layer 200 located below the dummy gate 210 is removed, and a new gate dielectric layer may be formed in subsequent processing steps. These processes may be selected flexibly according to structure designs and technical standards of the semiconductor devices.

Since the gate dielectric layer and the gate stack are formed inside the reverse taper shaped opening 410, even if the bottom width of the reverse taper shaped opening is small, the whole of the reverse taper shaped opening can still be easily filled when forming the gate stack because the upper width of the reverse taper shaped opening is relatively large. Thus, defects like voids are well avoided, processing difficulty is alleviated, and device yield is improved.

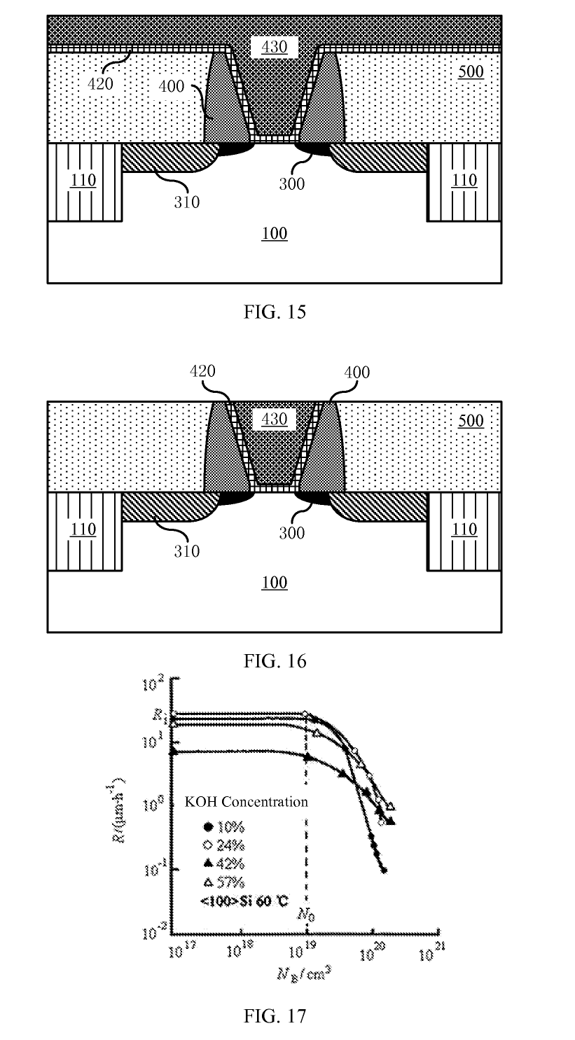

With reference to FIGS. 1 and 14-16, step S107 is performed to form a gate, which is planarized at the meantime. Optionally, the dielectric layer 200 may be kept to serve as a gate dielectric layer 420. In the present embodiment, the dielectric layer 200 is removed at step S106 and a gate dielectric layer 420 is formed, as shown in FIG. 14, while the material of the gate dielectric layer 420 may be SiO₂, Si₃N₄, or SiO₂N₂, or a high-k material selected from a group consisting of HfO₂, HfSiO, HfSiON, HfTaO, HfTiO, HfZrO, Al₂O₃, La₂O₃, ZrO₂, and LaAlO, or combinations of these materials. The gate dielectric layer 420 may be formed by CVD or Atom Layer Deposition (ALD). Typically, the thickness of the gate dielectric layer 420 is in the range of 2 nm-10 nm. Next, as shown in FIG. 15, a gate 430 is formed on the gate dielectric layer 420 to fill the opening 410. the gate 430 may be formed by depositing heavily doped poly-Si, or alternatively, by firstly forming a work function metal layer (which is, for example, TaC, TiN, TaTbN, TaErN, TaYbN, TaSiN, HfSiN, MoSiN, RuTaₓ, NiTaₓ for NMOS, while MoNₓ, TiSiN, TiCN, TaAlC, TiAlN, TaN, PtSiₓ, Ni₃Si, Pt, Ru, Ir, Mo, HfRu, RuOₓ for PMOS) with a thickness of 1 nm-20 nm (for example, 3 nm, 5 nm, 8 nm, 10 nm, 12 nm or 15 nm) and then forming heavily doped poly-Si, Ti, Co, Ni, Al, W or an alloy thereof on the work function metal layer. Finally, planarization is performed through chemical mechanical polish (CMP), such that the upper surface of the gate 430 is level with the upper surface of the interlayer dielectric layer 500, so as to form a gate stack structure as shown in FIG. 16.

Then, the manufacturing of the semiconductor structure is completed according to conventional semiconductor manufacturing processes, for example, depositing a dielectric layer to cover the source/drain regions and the gate stack, etching the interlayer dielectric layer to expose the source/drain regions to form contact holes, and filling metal into the contact holes, as well as subsequent steps for multi-layer metal interconnection.

The present invention further provides a semiconductor structure, as shown in FIG. 16. The semiconductor structure comprises a substrate 100, a gate 430, a gate dielectric layer 420, sidewall spacers 400, and source/drain regions 310. The gate 430 is located on the substrate 100 and is in the shape of a reverse taper, whose cross section is a reverse trapezoid. The gate dielectric layer 420 is sandwiched between the gate 430 and the substrate 100, or alternatively, the gate dielectric layer 420 covers the sidewalls and the bottom of the gate dielectric layer 420. The sidewall spacers 400 are located on the sidewalls of the gate 430. The source/drain regions 310 are formed within the substrate and located on opposite sides of the gate stack. Optionally, the semiconductor structure further comprises source/drain extension regions 300, which are embedded into the substrate 100 and located between the source/drain regions 310 and the channel region under the gate. The present invention provides such a semiconductor structure with gates in the shape of a reverse taper that is capable of suppressing defects like voids or gaps in the gate, thereby improving performances and reliability of the device.

Although the exemplary embodiments and their advantages have been described in detail, it should be understood that various alternations, substitutions and modifications may be made to the embodiments without departing from the spirit of the present invention and the scope as defined by the appended claims. For other examples, it may be easily recognized by a person of ordinary skill in the art that the order of processing steps may be changed without departing from the scope of the present invention.

In addition, the scope to which the present invention is applied is not limited to the process, mechanism, manufacture, material composition, means, methods and steps described in the specific embodiments in the specification. According to the disclosure of the present invention, a person of ordinary skill in the art would readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A method for manufacturing a semiconductor structure, comprising:
(a) providing a substrate, and forming a dielectric layer and a dummy gate layer on the substrate;
(b) performing doping and annealing to the dummy gate layer;
(c) patterning the dummy gate layer to form a dummy gate, wherein the top cross section of the dummy gate is larger than the bottom cross section of the dummy gate;
(d) forming sidewall spacers and source/drain regions;
(e) depositing an interlayer dielectric layer and planarizing the interlayer dielectric layer;
(f) removing the dummy gate to form an opening within the sidewall spacers; and
(g) forming a gate in the opening.

2. The method of claim 1, wherein at step (b), the doping method is diffusion or ion implantation, and the dopant ion is the ion of B, P, or As.

3. The method of claim 1, wherein at step (b), the doping concentration at the surface of the dummy gate layer is 1×10¹⁹ cm⁻³ to 1×10²¹ cm⁻³; and the annealing is performed such that the distribution of doping concentration within the dummy gate layer is gradually lower inwards from the surface of the dummy gate layer.

4. The method of claim 1, wherein at step (c), patterning the dummy gate layer to form the dummy gate comprises:
forming a hard mask layer on the dummy gate layer, wherein the hard mask layer corresponds to the shape of the top surface of the dummy gate to be formed; and
wet etching the exposed dummy gate layer using KOH, TMAH, or EDP.

5. The method of claim 4, further comprising, prior to wet etching, etching the exposed dummy gate layer through reactive ion etching.

6. The method of claim 1, wherein
step (d) further comprises forming source/drain extension regions prior to the formation of the source/drain regions; and
step (d) further comprises forming silicide contacts on the surfaces of the source/drain regions after the formation of the source/drain regions.

7. The method of claim 6, further comprising removing the exposed dielectric layer after the formation of the dummy gate at step (c) or prior to the formation of the silicide contacts at step (d).

8. The method of claim 1, further comprising removing the dielectric layer located below the dummy gate at step (f).

9. The method of claim 1, further comprising, at step (g), forming a gate dielectric layer in the opening prior to the formation of the gate, wherein the material of the gate dielectric layer comprises at least one material selected from a group consisting of SiO₂, Si₃N₄, HfO₂, HfSiO, HfSiON, HfTaO, HfTiO, HfZrO, Al₂O₃, La₂O₃, ZrO₂, and LaAlO.

10. A semiconductor structure, which comprises a substrate, a gate stack, sidewall spacers, and source/drain regions, wherein
the gate stack is located on the substrate and comprises a gate dielectric layer and a gate, and the top cross section of the gate is larger than the bottom cross section of the gate, the gate dielectric layer being sandwiched between the gate and the substrate, or alternatively, the gate dielectric layer being covering the sidewalls and the bottom of the gate;
the sidewall spacers are located on both sides of the gate stack; and
the source/drain regions are formed within the substrate and located on opposite sides of the gate stack.

11. The semiconductor structure of claim 10, wherein the angle between the sidewalls of the gate and the substrate is in the range of 45° to 85°.

12. The method of claim 3, wherein at step (c), patterning the dummy gate layer to form the dummy gate comprises:
forming a hard mask layer on the dummy gate layer, wherein the hard mask layer corresponds to the shape of the top surface of the dummy gate to be formed; and
wet etching the exposed dummy gate layer using KOH, TMAH, or EDP.

13. The method of claim 8, further comprising, at step (g), forming a gate dielectric layer in the opening prior to the formation of the gate, wherein the material of the gate dielectric layer comprises at least one material selected from a group consisting of SiO₂, Si₃N₄, HfO₂, HfSiO, HfSiON, HfTaO, HfTiO, HfZrO, Al₂O₃, La₂O₃, ZrO₂, and LaAlO.
